(19) United States
(12) Patent Application Publication
(10) Pub. No.: US 2026/0323875 A1
(43) Pub. Date: Oct. 15, 2026

(54) MANIFOLD

(71) Applicant: NIDEC CORPORATION, Kyoto (JP)

(72) Inventors: Masahiro OTANI, Kyoto (JP); Takehito TAMAOKA, Kyoto (JP); Takaya OKUNO, Kyoto (JP); Tadahiro KURAMOTO, Kyoto (JP)

(21) Appl. No.: 19/640,498

(22) Filed: Apr. 7, 2026

Related U.S. Application Data
(60) Provisional application No. 63/788,355, filed on Apr. 14, 2025.

(30) Foreign Application Priority Data
Dec. 4, 2025 (JP) 2025-230727

(51) Int. Cl. H05K 7/20

(52) U.S. Cl. CPC H05K 7/20272; H05K 7/20254

(57) ABSTRACT

A manifold includes a manifold body portion, a distribution-side tray portion, and a collection-side tray portion. The manifold body portion includes a distribution-side connection portion, a distribution-side flow path portion, a collection-side flow path portion, and a collection-side connection portion. The distribution-side connection portion is positioned at an end portion on one side in a first direction, into which a cooled refrigerant flows from an external flow path via a first joint fluidly connected to the distribution-side connection portion. The distribution-side flow path portion distributes, to a plurality of cooling units, the refrigerant flowing from the distribution-side connection portion. The collection-side flow path portion collects the refrigerant having absorbed heat from the plurality of cooling units. The collection-side connection portion is positioned at an end portion on the other side in the first direction.

### CROSS-REFERENCE TO RELATED APPLICATIONS

The present application claims priority under 35 U.S.C. § 119 to Japanese Patent Application No. 2025-230727, filed on Dec. 4, 2025, and is a non-provisional application based on US Patent Application No. 63/788,355, filed on Apr. 14, 2025, the entire contents of which are incorporated herein by reference.

### 1. FIELD OF THE INVENTION

Example embodiments described herein relate to manifolds.

### 2. Background

There has been known a cooling module including a distribution manifold that distributes a refrigerant cooled in an external flow path to a plurality of cooling units and a collection manifold that collects the refrigerant from the plurality of cooling units to which the refrigerant has been distributed and causes the refrigerant to flow out to the external flow path.

A joint into which the refrigerant flows from the external flow path via a flow path pipe is connected to the distribution manifold. Meanwhile, a joint through which the refrigerant flows out to the external flow path via a flow path pipe is connected to the collection manifold.

Unfortunately, the distribution manifold and the collection manifold in the related art may cause the leaking refrigerant to affect the surrounding components when the refrigerant leaks from a connection portion with the joint.

### SUMMARY

A manifold according to an example embodiment includes a manifold body portion, a distribution-side tray portion, and a collection-side tray portion. The manifold body portion includes a distribution-side connection portion, a distribution-side flow path portion, a collection-side flow path portion, and a collection-side connection portion. The distribution-side connection portion is positioned at an end portion on one side in a first direction, into which a cooled refrigerant flows from an external flow path via a first joint fluidly connected to the distribution-side connection portion. The distribution-side flow path portion distributes, to a plurality of cooling units, the refrigerant flowing from the distribution-side connection portion. The collection-side flow path portion collects the refrigerant having absorbed heat from the plurality of cooling units. The collection-side connection portion is positioned at an end portion on another side in the first direction, through which the refrigerant flows out from the collection-side flow path portion to the external flow path via a second joint fluidly connected to the collection-side connection portion. The distribution-side tray portion surrounds at least a periphery of a lower portion on one side in the first direction of the distribution-side connection portion and is provided integrally with the manifold body portion. The collection-side tray portion surrounds at least a periphery of a lower portion on the other side in the first direction of the collection-side connection portion and is provided integrally with the manifold body portion.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is an explanatory top view of a cooling module according to an example embodiment of the present disclosure.

FIG. 2 is a perspective view of a distribution-side connection portion and a distribution-side tray portion according to an example embodiment of the present disclosure.

FIG. 3 is a perspective view of a collection-side connection portion and a collection-side tray portion according to an example embodiment of the present disclosure.

FIG. 4 is a top view of a distribution-side connection portion and a distribution-side tray portion according to an example embodiment of the present disclosure.

FIG. 5 is a top view of a collection-side connection portion and a collection-side tray portion according to an example embodiment of the present disclosure.

FIG. 6 is a side view of a distribution-side connection portion and a distribution-side tray portion according to an example embodiment of the present disclosure.

FIG. 7 is a side view of a collection-side connection portion and a collection-side tray portion according to an example embodiment of the present disclosure.

FIG. 8 is a cross-sectional view illustrating a shape of a distribution-side connection flow path according to a modification of an example embodiment of the present disclosure.

FIG. 9 is a cross-sectional view illustrating a shape of a collection-side connection flow path according to a modification of an example embodiment of the present disclosure.

### DETAILED DESCRIPTION

Hereinafter, examples of manifolds according to example embodiments of the present disclosure (hereinafter referred to as “example embodiments”) will be described in detail with reference to the drawings. The present disclosure is not limited by the example embodiments. In the following example embodiments, components having the same function are denoted by the same reference numeral, and redundant description is omitted.

In the following example embodiments, expressions such as “constant”, “orthogonal”, “perpendicular”, and “parallel” may be used, but these expressions do not need to be strictly “constant”, “orthogonal”, “perpendicular”, and “parallel”. That is, each of the above-described expressions allows, for example, a deviation in manufacturing accuracy, installation accuracy, or the like.

In each of the drawings referred to below, in order to make the description easy to understand, an orthogonal coordinate system in which an X-axis direction, a Y-axis direction, and a Z-axis direction orthogonal or substantially orthogonal to each other are defined and a Z-axis positive direction is a vertically upward direction may be illustrated.

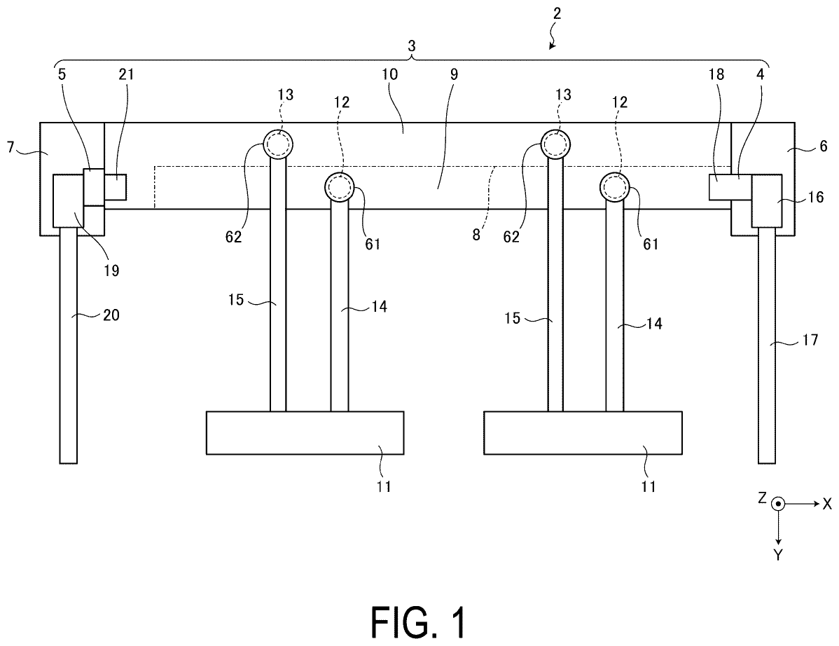

First, with reference to FIG. 1, a configuration of a manifold according to an example embodiment will be described. FIG. 1 is an explanatory top view of a manifold 2 according to the present example embodiment. The manifold 2 according to the present example embodiment is a flow path member that distributes a refrigerant flowing in from an external flow path, which is omitted in illustration, to a plurality of cooling units 11, collects, from the plurality of cooling units 11, the refrigerant having absorbed heat from heat sources in the cooling units 11, and causes the refrigerant to flow out to the external flow path again.

In one example, the external flow path includes a refrigerant circulation device. The refrigerant circulation device is a device that cools the refrigerant flowing in from the manifold 2 and sends the refrigerant to the cooling unit 11 via the manifold 2 again. The refrigerant circulation device may include a radiator.

In one example, the cooling unit 11 is a cold plate. The cooling unit 11 is in thermal contact with the heat source. In one example, the heat source is an arithmetic device such as a central processing unit (CPU). Each of the cooling units 11 includes an internal flow path through which the refrigerant flows. The cooling unit 11 includes a plurality of fins that cause the refrigerant flowing through the internal flow path to absorb heat.

As illustrated in FIG. 1, the manifold 2 includes a manifold body portion 3, a distribution-side tray portion 6, and a collection-side tray portion 7. The manifold body portion 3 includes a distribution-side connection portion 4, a distribution-side flow path portion 9, a collection-side flow path portion 10, and a collection-side connection portion 5.

The distribution-side connection portion 4 is positioned at an end portion on a positive side in the X-axis direction, which is an end portion on one side of the manifold body portion 3 in a first direction. A cooled refrigerant flows in the distribution-side connection portion 4 from the external flow path (illustration omitted) via a first joint 16 fluidly connected and a distribution-side flow path pipe 17. The refrigerant flowing in the distribution-side connection portion 4 flows out to the distribution-side flow path portion 9 via a distribution-side connection flow path 18 that fluidly connects the distribution-side connection portion 4 and the distribution-side flow path portion 9.

The distribution-side flow path portion 9 is a flow path portion that distributes the refrigerant flowing from the distribution-side connection portion 4 to the plurality of cooling units 11. Specifically, the distribution-side flow path portion 9 includes a plurality of distribution-side joint connection ports 12. A distribution-side joint 61 is fluidly connected to the distribution-side joint connection port 12. The distribution-side joint 61 is fluidly connected to the inflow port of the refrigerant of the cooling unit 11 via the flow path pipe 14.

The collection-side flow path portion 10 is a flow path portion that collects, from the plurality of cooling units 11, the refrigerant having absorbed heat while flowing through the cooling unit 11. Specifically, the collection-side flow path portion 10 includes a plurality of collection-side joint connection ports 13. A collection-side joint 62 is fluidly connected to the collection-side joint connection port 13. The collection-side joint 62 is fluidly connected to the outflow port of the refrigerant of the cooling unit 11 via the flow path pipe 15. The distribution-side flow path portion 9 and the collection-side flow path portion 10 are separated from each other by a partition wall 8 provided inside the manifold body portion 3.

The collection-side connection portion 5 is positioned at an end portion on a negative side in the X-axis direction, which is the other end portion of the manifold body portion 3 in the first direction. The refrigerant having absorbed heat flows from the collection-side flow path portion 10 to the collection-side connection portion 5 via a collection-side connection flow path 21 that fluidly connects the collection-side flow path portion 10 and the collection-side connection portion 5.

The refrigerant flowing in the collection-side connection portion 5 flows out to the external flow path (illustration omitted) via a second joint 19 fluidly connected to the collection-side connection portion 5 and a collection-side flow path pipe 20. The refrigerant cooled in the external flow path flows in the distribution-side flow path portion 9 again from the distribution-side connection portion 4 via the distribution-side flow path pipe 17 and the first joint 16.

The distribution-side tray portion 6 surrounds at least a periphery of a lower portion on the positive side in the X-axis direction of the distribution-side connection portion 4, and is provided integrally with the manifold body portion 3. The collection-side tray portion 7 surrounds at least a lower portion on the negative side in the X-axis direction of the collection-side connection portion 5 and is provided integrally with the manifold body portion 3.

The manifold 2 allows the distribution-side tray portion 6 to receive the refrigerant even when the refrigerant leaks from the connection portion between the distribution-side connection portion 4 and the first joint 16, thereby preventing the leaking refrigerant from affecting surrounding components.

The manifold 2 allows the collection-side tray portion 7 to receive the refrigerant even when the refrigerant leaks from the connection portion between the collection-side connection portion 5 and the second joint 19, thereby preventing the leaking refrigerant from affecting surrounding components.

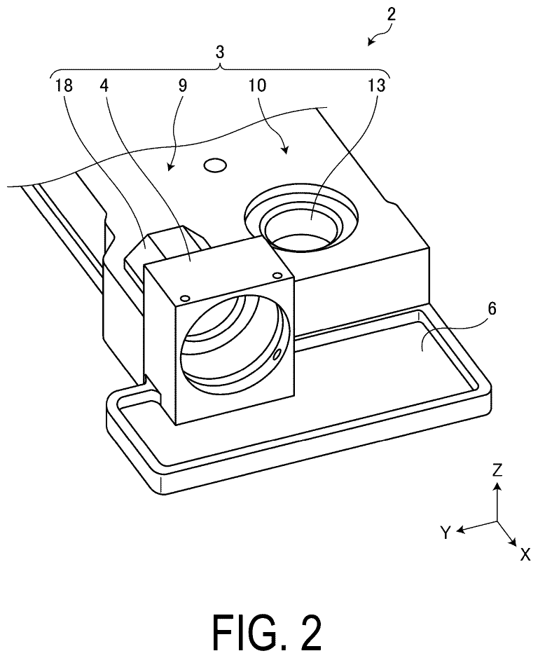

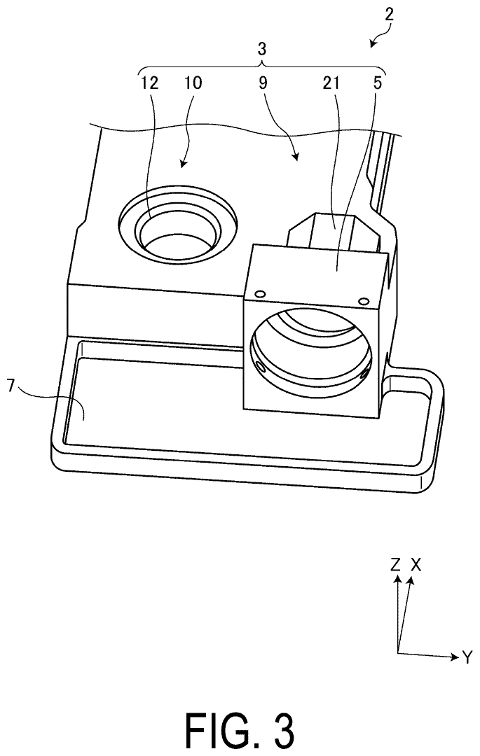

Next, with reference to FIGS. 2 to 7, the configurations of the distribution-side connection portion 4, the distribution-side tray portion 6, the collection-side connection portion 5, and the collection-side tray portion 7 will be described more specifically. FIG. 2 is a perspective view of the distribution-side connection portion 4 and the distribution-side tray portion 6 according to the present example embodiment. FIG. 3 is a perspective view of the collection-side connection portion 5 and the collection-side tray portion 7 according to the present example embodiment.

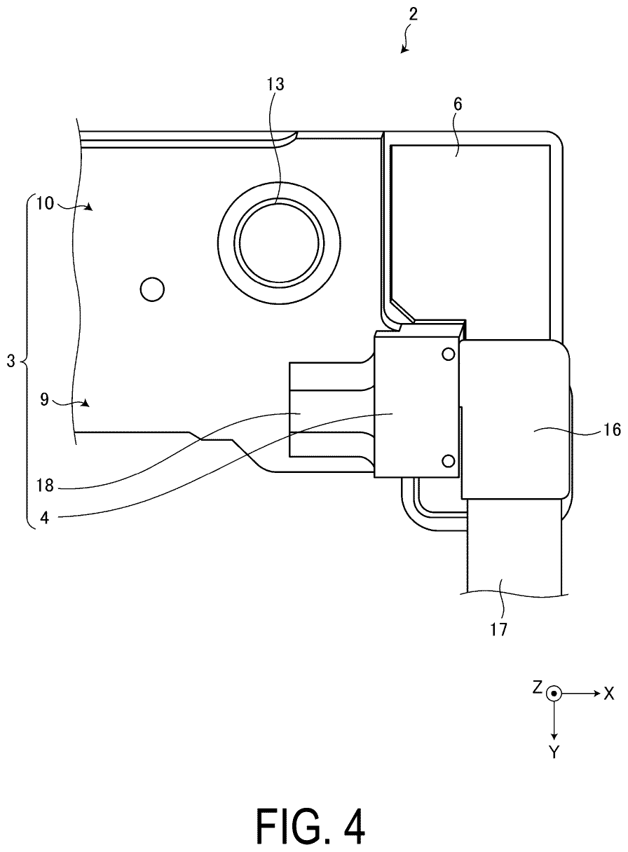

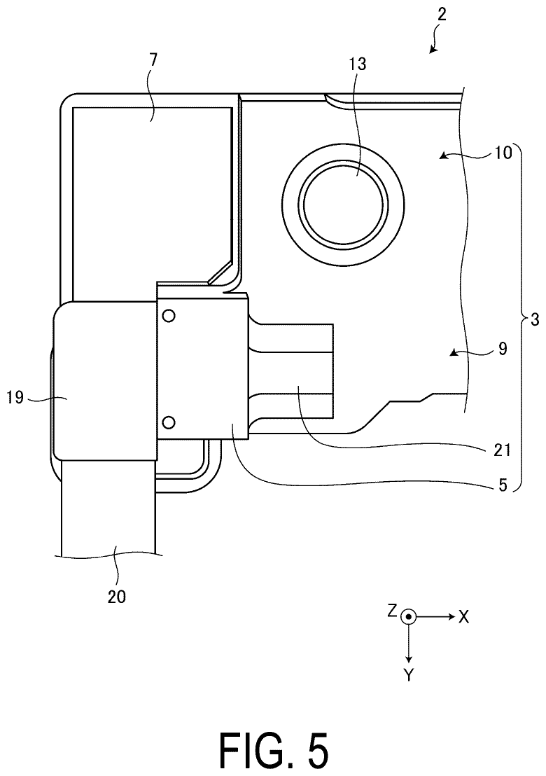

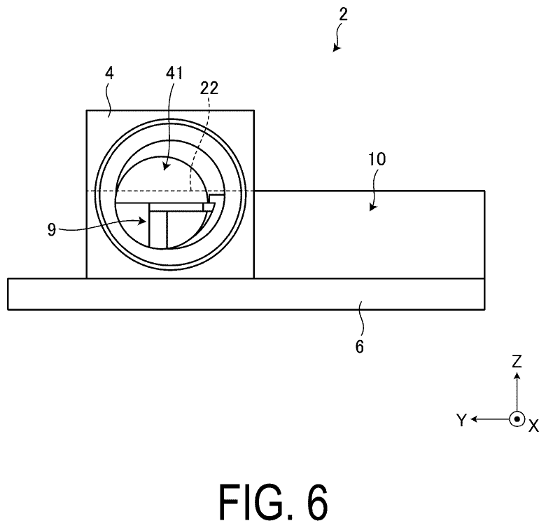

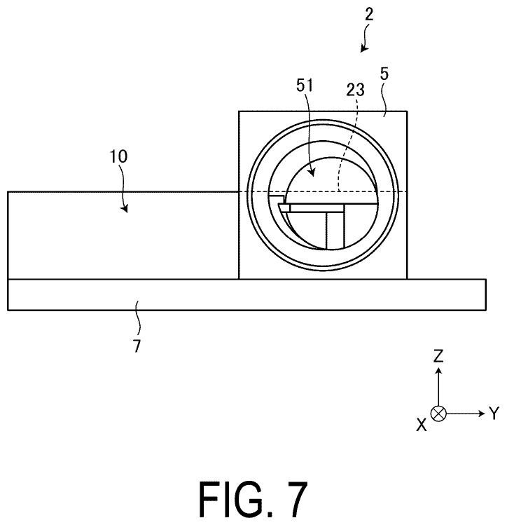

FIG. 4 is a top view of the distribution-side connection portion 4 and the distribution-side tray portion 6 according to the present example embodiment. FIG. 5 is a top view of the collection-side connection portion 5 and the collection-side tray portion 7 according to the present example embodiment. FIG. 6 is a side view of the distribution-side connection portion 4 and the distribution-side tray portion 6 according to the present example embodiment. FIG. 7 is a side view of the collection-side connection portion 5 and the collection-side tray portion 7 according to the present example embodiment.

As illustrated in FIG. 2, the distribution-side tray portion 6 is provided integrally with the manifold body portion 3 and the distribution-side connection portion 4. In other words, there is no gap between the distribution-side tray portion 6 and the manifold body portion 3 and the distribution-side connection portion 4. The distribution-side tray portion 6 includes an edge portion that rises from an outer peripheral portion of a bottom surface portion to the positive side in the Z-axis direction.

Thus, the manifold 2 allows the refrigerant leaking from the connection portion between the distribution-side connection portion 4 and the first joint 16 to be prevented from moving between the distribution-side tray portion 6 and the manifold body portion 3 and the distribution-side connection portion 4 and leaking to the outside of the manifold 2.

As illustrated in FIG. 3, the collection-side tray portion 7 is provided integrally with the manifold body portion 3 and the collection-side connection portion 5. In other words, there is no gap between the collection-side tray portion 7 and the manifold body portion 3 and the collection-side connection portion 5. The collection-side tray portion 7 includes an edge portion that rises from an outer peripheral portion of a bottom surface portion to the positive side in the Z-axis direction.

Thus, the manifold 2 allows the refrigerant leaking from the connection portion between the collection-side connection portion 5 and the second joint 19 to be prevented from moving between the collection-side tray portion 7 and the manifold body portion 3 and the collection-side connection portion 5 and from leaking to the outside of the manifold 2.

As illustrated in FIG. 2, the distribution-side tray portion 6 includes the bottom surface portion connected to a bottom surface portion of the distribution-side connection portion 4. Thus, the manifold 2 can reduce a change in a position of the flow path in the up-down direction in the flow path between the distribution-side connection portion 4 and the distribution-side flow path portion 9, thereby reducing the flow path resistance. The manifold 2 allows the refrigerant to move along the distribution-side connection portion 4 and to be accommodated in the distribution-side tray portion 6 when the refrigerant leaks at the periphery of the first joint 16, thereby reducing leakage of the refrigerant to the outside.

As illustrated in FIG. 3, the collection-side tray portion 7 includes the bottom surface portion connected to a bottom surface portion the collection-side connection portion 5. Thus, the manifold 2 can reduce a change in a position of the flow path in the up-down direction in the flow path the collection-side connection portion 5 and the collection-side flow path portion 10, thereby reducing the flow path resistance. The manifold 2 allows the refrigerant to move along the collection-side connection portion 5 and to be accommodated in the collection-side tray portion 7 when the refrigerant leaks at the periphery of the second joint 19. Thus, leakage of the refrigerant to the outside can be suppressed.

As illustrated in FIG. 4, the distribution-side connection portion 4 is positioned on the positive side in the Y-axis direction, which is one side in a second direction orthogonal or substantially orthogonal to the X-axis direction, at the end portion of the manifold body portion 3 on the positive side in the X-axis direction, and the distribution-side flow path pipe 17 is fluidly connected from the positive side in the Y-axis direction to the first joint 16 fluidly connected. With this, in the manifold 2, the distribution-side flow path pipe 17 can be reduced in length.

As illustrated in FIG. 5, the collection-side connection portion 5 is positioned on the positive side in the Y-axis direction at the end portion of the manifold body portion 3 on the negative side in the X-axis direction, and the collection-side flow path pipe 20 is fluidly connected from the positive side in the Y-axis direction to the second joint 19 fluidly connected. With this, in the manifold 2, the collection-side flow path pipe 20 can be reduced in length.

As illustrated in FIG. 4, the end edge of the distribution-side tray portion 6 on the positive side in the Y-axis direction is positioned on the positive side in the Y-axis direction with respect to the connection portion between the first joint 16 fluidly connected to the distribution-side connection portion 4 and the distribution-side flow path pipe 17.

With this, in the manifold 2, when the refrigerant leaks from the connection portion between the first joint 16 and the distribution-side flow path pipe 17, the refrigerant leaking from the end edge of the distribution-side flow path pipe 17 on the negative side in the Y-axis direction can be accommodated more securely in the distribution-side tray portion 6.

As illustrated in FIG. 5, the end edge of the collection-side tray portion 7 on the positive side in the Y-axis direction is positioned on the positive side in the Y-axis direction with respect to the connection portion between the second joint 19 fluidly connected to the collection-side connection portion 5 and the collection-side flow path pipe 20.

With this, in the manifold 2, when the refrigerant leaks from the connection portion between the second joint 19 and the collection-side flow path pipe 20, the refrigerant leaking from the end edge of the collection-side flow path pipe 20 on the negative side in the Y-axis direction can be accommodated more securely in the collection-side tray portion 7.

As illustrated in FIGS. 4 and 5, the end edges of the distribution-side tray portion 6 and the collection-side tray portion 7 on the negative side in the Y-axis direction are positioned at the same position as the end edge of the manifold body portion 3 on the negative side in the Y-axis direction, or are positioned on the positive side in the Y-axis direction with respect to the same position. With this, in the manifold 2, an increase in size of the outer shape including the distribution-side tray portion 6 and the collection-side tray portion 7 can be suppressed.

As illustrated in FIG. 4, the end edge of the distribution-side tray portion 6 on the positive side in the X-axis direction is positioned at the same position as the end edge of the first joint 16, which is fluidly connected to the distribution-side connection portion 4, on the positive side in the X-axis direction, or is positioned on the negative side in the X-axis direction with respect to the same position. With this, in the manifold 2, an increase in size of the outer shape including the distribution-side tray portion 6 and the collection-side tray portion 7 can be suppressed.

As illustrated in FIG. 5, the end edge of the collection-side tray portion 7 on the negative side in the X-axis direction is positioned at the same position as the end edge of the second joint 19, which is fluidly connected to the collection-side connection portion 5, on the negative side in the X-axis direction, or is positioned on the positive side in the X-axis direction with respect to the same position. With this, in the manifold 2, an increase in size of the outer shape including the distribution-side tray portion 6 and the collection-side tray portion 7 can be suppressed.

As illustrated in FIG. 6, at least a portion of a flow path 41 of the refrigerant in the distribution-side connection portion 4 is positioned below a top surface 22 of the distribution-side flow path portion 9. With this, the manifold 2 can reduce the flow path resistance of the refrigerant flowing in from the distribution-side connection portion 4 to the distribution-side flow path portion 9.

As illustrated in FIG. 7, at least a portion of a flow path 51 of the refrigerant in the collection-side connection portion 5 is positioned below a top surface 23 of the collection-side flow path portion 10. With this, the manifold 2 can reduce the flow path resistance of the refrigerant flowing in from the collection-side flow path portion 10 to the collection-side connection portion 5.

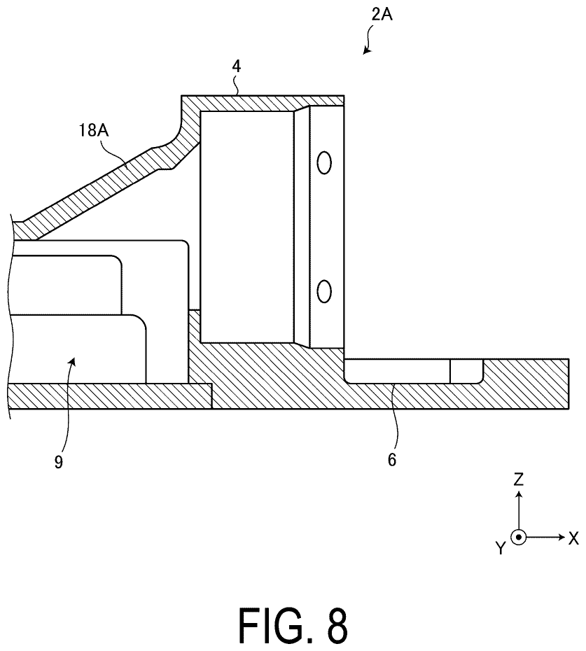

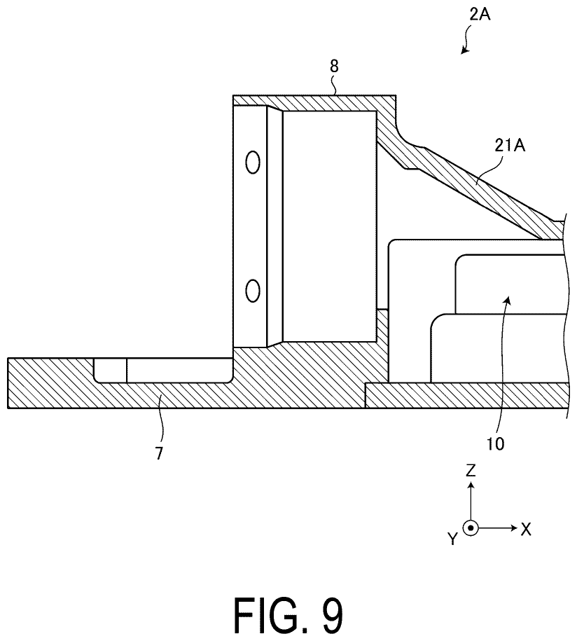

Next, with reference to FIGS. 8 and 9, a distribution-side connection flow path 18A and a collection-side connection flow path 21A according to a modification of an example embodiment of the present disclosure will be described. FIG. 8 is a cross-sectional view illustrating a shape of the distribution-side connection flow path 18A according to the modification of the present example embodiment. FIG. 9 is a cross-sectional view illustrating a shape of the collection-side connection flow path 21A according to the modification of the present example embodiment.

As illustrated in FIG. 8, the distribution-side connection flow path 18A according to the modification includes an inclination from the distribution-side connection portion 4 toward the distribution-side flow path portion 9. With this, a manifold 2A according to the modification can reduce the flow path resistance of the refrigerant flowing from the distribution-side connection portion 4 to the distribution-side flow path portion 9.

As illustrated in FIG. 9, the collection-side connection flow path 21A according to the modification includes an inclination from the collection-side connection portion 5 toward the collection-side flow path portion 10. With this, the manifold 2A according to the modification can reduce the flow path resistance of the refrigerant flowing from the collection-side connection portion 5 to the collection-side flow path portion 10.

Note that the present technology can have configurations such as the following.
(1)

A manifold, including:
a manifold body portion including:
a distribution-side connection portion positioned at an end portion on one side in a first direction, into which a cooled refrigerant flows from an external flow path via a first joint fluidly connected to the distribution-side connection portion;
a distribution-side flow path portion to distribute, to a plurality of cooling units, the refrigerant flowing from the distribution-side connection portion;
a collection-side flow path portion to collect the refrigerant after the refrigerant has absorbed heat from the plurality of cooling units; and
a collection-side connection portion positioned at an end portion on the other side in the first direction, through which the refrigerant flows out from the collection-side flow path portion to the external flow path via a second joint fluidly connected to the collection-side connection portion;
a distribution-side tray portion that surrounds at least a periphery of a lower portion on one side in the first direction of the distribution-side connection portion and is provided integrally with the manifold body portion; and
a collection-side tray portion that surrounds at least a periphery of a lower portion on the other side in the first direction of the collection-side connection portion and is provided integrally with the manifold body portion.
(2)

The manifold according to Item (1), wherein
the distribution-side tray portion is provided integrally with the manifold body portion and the distribution-side connection portion, and
the collection-side tray portion is provided integrally with the manifold body portion and the collection-side connection portion.
(3)

The manifold according to Item (1) or (2), wherein
the distribution-side tray portion includes a bottom surface portion connected to a bottom surface portion of the distribution-side connection portion, and
the collection-side tray portion includes a bottom surface portion connected to a bottom surface portion of the collection-side connection portion.
(4)

The manifold according to any one of Items (1) to (3), wherein
the distribution-side connection portion is positioned on one side in a second direction orthogonal or substantially orthogonal to the first direction of an end portion on one side in the first direction of the manifold body portion, a distribution-side flow path pipe is fluidly connected to the first joint, which is fluidly connected to the distribution-side connection portion, from one side in the second direction,
the collection-side connection portion is positioned on one side in the second direction of an end portion on the other side in the first direction of the manifold body portion, and a collection-side flow path pipe is fluidly connected to the second joint, which is fluidly connected to the collection-side connection portion, from one side in the second direction.
(5)

The manifold according to any one of Items (1) to (4), wherein
at least a portion of a flow path of the refrigerant in the distribution-side connection portion is positioned below a top surface of the distribution-side flow path portion, and
at least a portion of a flow path of the refrigerant in the collection-side connection portion is positioned below a top surface of the collection-side flow path portion.
(6)

The manifold according to Item (4), wherein
an end edge on one side in the second direction of the distribution-side tray portion is positioned on one side in the second direction with respect to a connection portion between the first joint fluidly connected to the distribution-side connection portion and the distribution-side flow path pipe, and
an end edge on one side in the second direction of the collection-side tray portion is positioned on one side in the second direction with respect to a connection portion between the second joint fluidly connected to the collection-side connection portion and the collection-side flow path pipe.
(7)

The manifold according to any one of Items (1) to (6), wherein
end edges on the other side in the second direction of the distribution-side tray portion and the collection-side tray portion are positioned at the same position as an end edge on the other side in the second direction of the manifold body portion or are positioned on one side in the second direction with respect to the same position.
(8)

The manifold according to any one of Items (1) to (7), wherein
an end edge on one side in the first direction of the distribution-side tray portion is positioned at the same position as an end edge on one side in the first direction of the first joint fluidly connected to the distribution-side connection portion or is positioned on the other side in the first direction with respect to the same position, and
an end edge on the other side in the first direction of the collection-side tray portion is positioned at the same position as an end edge on the other side in the first direction of the second joint fluidly connected to the collection-side connection portion or is positioned on one side in the first direction with respect to the same position.
(9)

The manifold according to any one of Items (1) to (8), wherein
a distribution-side connection flow path that fluidly connects the distribution-side connection portion and the distribution-side flow path portion includes an inclination from the distribution-side connection portion toward the distribution-side flow path portion, and
a collection-side connection flow path that fluidly connects the collection-side connection portion and the collection-side flow path portion includes an inclination from the collection-side connection portion toward the collection-side flow path portion.

Further effects and modified examples can be easily derived by those skilled in the art. Therefore, the broader aspects of the present disclosure are not limited to the specific details and representative example embodiments shown and described above. Accordingly, various modifications may be made without departing from the spirit or scope of the general inventive concept as defined by the appended claims and their equivalents.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A manifold, comprising:
a manifold body portion including:
a distribution-side connection portion positioned at an end portion on one side in a first direction, into which a cooled refrigerant flows from an external flow path via a first joint fluidly connected to the distribution-side connection portion;
a distribution-side flow path portion to distribute, to a plurality of cooling units, the refrigerant flowing from the distribution-side connection portion;
a collection-side flow path portion to collect the refrigerant after the refrigerant has absorbed heat from the plurality of cooling units; and
a collection-side connection portion positioned at an end portion on another side in the first direction, through which the refrigerant flows out from the collection-side flow path portion to the external flow path via a second joint fluidly connected to the collection-side connection portion;
a distribution-side tray portion that surrounds at least a periphery of a lower portion on one side in the first direction of the distribution-side connection portion and is provided integrally with the manifold body portion; and
a collection-side tray portion that surrounds at least a periphery of a lower portion on the other side in the first direction of the collection-side connection portion and is provided integrally with the manifold body portion.

2. The manifold according to claim 1, wherein
the distribution-side tray portion is provided integrally with the manifold body portion and the distribution-side connection portion; and
the collection-side tray portion is provided integrally with the manifold body portion and the collection-side connection portion.

3. The manifold according to claim 1, wherein
the distribution-side tray portion includes a bottom surface portion connected to a bottom surface portion of the distribution-side connection portion; and
the collection-side tray portion includes a bottom surface portion connected to a bottom surface portion of the collection-side connection portion.

4. The manifold according to claim 1, wherein
the distribution-side connection portion is positioned on one side in a second direction orthogonal or substantially orthogonal to the first direction of an end portion on one side in the first direction of the manifold body portion, a distribution-side flow path pipe is fluidly connected to the first joint, which is fluidly connected to the distribution-side connection portion, from one side in the second direction;
the collection-side connection portion is positioned on one side in the second direction of an end portion on the other side in the first direction of the manifold body portion, and a collection-side flow path pipe is fluidly connected to the second joint, which is fluidly connected to the collection-side connection portion, from one side in the second direction.

5. The manifold according to claim 1, wherein
at least a portion of a flow path of the refrigerant in the distribution-side connection portion is positioned below a top surface of the distribution-side flow path portion; and
at least a portion of a flow path of the refrigerant in the collection-side connection portion is positioned below a top surface of the collection-side flow path portion.

6. The manifold according to claim 4, wherein
an end edge on one side in the second direction of the distribution-side tray portion is positioned on one side in the second direction with respect to a connection portion between the first joint fluidly connected to the distribution-side connection portion and the distribution-side flow path pipe; and
an end edge on one side in the second direction of the collection-side tray portion in the second direction is positioned on one side in the second direction with respect to a connection portion between the second joint fluidly connected to the collection-side connection portion and the collection-side flow path pipe.

7. The manifold according to claim 1, wherein end edges on the other side in the second direction of the distribution-side tray portion and the collection-side tray portion are positioned at the same position as an end edge on the other side in the second direction of the manifold body portion in the second direction or are positioned on one side in the second direction with respect to the same position.

8. The manifold according to claim 1, wherein
an end edge on one side in the first direction of the distribution-side tray portion is positioned at the same position as an end edge on one side in the first direction of the first joint fluidly connected to the distribution-side connection portion or is positioned on the other side in the first direction with respect to the same position; and
an end edge on the other side in the first direction of the collection-side tray portion is positioned at the same position as an end edge on the other side in the first direction of the second joint fluidly connected to the collection-side connection portion, or is positioned on one side in the first direction with respect to the same position.

9. The manifold according to claim 1, wherein
a distribution-side connection flow path that fluidly connects the distribution-side connection portion and the distribution-side flow path portion includes an inclination from the distribution-side connection portion toward the distribution-side flow path portion; and
a collection-side connection flow path that fluidly connects the collection-side connection portion and the collection-side flow path portion includes an inclination from the collection-side connection portion toward the collection-side flow path portion.
